(19) United States
(12) Patent Application Publication
(10) Pub. No.: US 2006/0027171 A1
(43) Pub. Date: Feb. 9, 2006

(54) Wafer boat for reducing wafer warpage

(75) Inventors: Chun-Keng Hsu, Taoyuan (TW); Chun-Chih Lin, Taipei City (TW)

Correspondence Address: TUNG & ASSOCIATES, Suite 120, 838 W. Long Lake Road, Bloomfield Hills, MI, 48302, US

(73) Assignee: Taiwan Semiconductor Manufacturing Co., Ltd.

(21) Appl. No.: 10/913,760

(22) Filed: Aug. 6, 2004

(51) Int. Cl. C23C 16/00

(52) U.S. Cl. 118/728

(57) ABSTRACT

A wafer boat which is suitable for supporting wafers in a process furnace is disclosed. The wafer boat includes a base plate, multiple support rods carried by the base plate and multiple wafer support pins carried by each of the support rods. Each of the wafer support pins has an upper surface disposed at an acute angle with respect to a longitudinal axis of each of the support rods. This causes contact of the wafer support pins with the wafer at the wafer's center of gravity and minimizes the contact surface area between the wafer support pins and each wafer.

### FIELD OF THE INVENTION

The present invention relates to furnaces used in the fabrication of semiconductor integrated circuits on semiconductor wafer substrates. More particularly, the present invention relates to a wafer boat having angled wafer support pins which contact a wafer at the center of gravity of the wafer to prevent or reduce wafer warpage and particle generation during processing.

### BACKGROUND OF THE INVENTION

The fabrication of various solid state devices requires the use of planar substrates, or semiconductor wafers, on which integrated circuits are fabricated. The final number, or yield, of functional integrated circuits on a wafer at the end of the IC fabrication process is of utmost importance to semiconductor manufacturers, and increasing the yield of circuits on the wafer is the main goal of semiconductor fabrication. After packaging, the circuits on the wafers are tested, wherein non-functional dies are marked using an inking process and the functional dies on the wafer are separated and sold. IC fabricators increase the yield of dies on a wafer by exploiting economies of scale. Over 1000 dies may be formed on a single wafer which measures from six to twelve inches in diameter.

In the semiconductor production industry, various processing steps are used to fabricate integrated circuits on a semiconductor wafer. These steps include the deposition of layers of different materials including metallization layers, passivation layers and insulation layers on the wafer substrate, as well as photoresist stripping and sidewall passivation polymer layer removal. In modern memory devices, for example, multiple layers of metal conductors are required for providing a multi-layer metal interconnection structure in defining a circuit on the wafer. A current drive in the semiconductor device industry is to produce semiconductors having an increasingly large density of integrated circuits which are ever-decreasing in size. These goals are achieved by scaling down the size of the circuit features in both the lateral and vertical dimensions. Vertical downscaling requires that the thickness of conductive and insulative films on the wafer be reduced by a degree which corresponds to shrinkage of the circuit features in the lateral dimension. Ultrathin device features will become increasingly essential for the fabrication of semiconductor integrated circuits in the burgeoning small/fast device technology.

Chemical vapor deposition (CVD) processes are widely used to form layers of materials on a semiconductor wafer. CVD processes include thermal deposition processes, in which a gas is reacted with the heated surface of a semiconductor wafer substrate, as well as plasma-enhanced CVD processes, in which a gas is subjected to electromagnetic energy in order to transform the gas into a more reactive plasma. Forming a plasma can lower the temperature required to deposit a layer on the wafer substrate, to increase the rate of layer deposition, or both. Other CVD processes include APCVD (atmospheric pressure chemical vapor deposition), and LPCVD (low pressure chemical vapor deposition). While APCVD systems have high equipment throughput, good uniformity and the capability to process large-diameter wafers, APCVD systems consume large quantities of process gas and often exhibit poor step coverage. Currently, LPCVD is used more often than APCVD because of its lower cost, higher production throughput and superior film properties. LPCVD is commonly used to deposit nitride, TEOS oxide and polysilicon films on wafer surfaces for front-end-of-line (FEOL) processes.

An example of a typical conventional vertical LPCVD furnace is generally indicated by reference numeral 10 in FIG. 1 and includes a base 12 on which is removably mounted a quartz tube 14. The interior of the quartz tube 14 defines a reaction chamber 16 for processing of as many as 150 wafers 29 held by a wafer boat 24 that is supported on the base 12 and contained in the reaction chamber 16. The wafer boat 24 may be a SiC (silicon carbide) wafer boat and typically includes a base plate 25 and a top plate 26 which are spanned by multiple vertical support rods 27.

As shown in FIG. 1A, multiple vertically-spaced wafer support pins 30 extend from each of the support rods 27, at substantially a 90-degree angle with respect to the longitudinal axis of the support rod 27. Each wafer support pin 30 typically has a pin length 30a of about 20 mm. Each wafer 29 is supported by a set of the wafer support pins 30 that extend from the respective support rods 27. Accordingly, the contact pins 30 contact the bottom of each wafer 29 at multiple pin contact points 31 disposed adjacent to the edge of the wafer 29, as shown in FIG. 1B. Each pin contact point 31 has a width 32 of typically about 10 mm.

A gas inlet tube 18 may extend downwardly through the quartz tube 14 into the reaction chamber 16, and a central gas inlet opening 20 may be provided in the top center of the quartz tube 14, for distributing reaction gases into the reaction chamber 16. A gas outlet 22 is provided typically in the base 12 for distributing exhaust gases from the reaction chamber 16. The gas outlet 22 may be located on the opposite side of the wafer boat 24 with respect to the gas inlet tube 18 to facilitate a more uniform flow of the reaction gases throughout the reaction chamber 16.

During LPCVD processes carried out in the conventional furnace 10, as many as 150 wafers 29 are processed in batches in order to maintain high wafer throughput. Process gases are introduced into the furnace 10 through the gas inlet tube 18 and/or gas inlet opening 20, and the wafers 29 are heated to facilitate deposition of chemical species from the process gases, onto the wafers 29. Exhaust gases are evacuated from the furnace 10 through the gas outlet 22.

One of the drawbacks associated with the wafer support pins 30 of the conventional wafer boat 24 is that the pin contact points 31 on the backside of each wafer 29 are not located at or near the center of gravity of the wafers 29, which is about 30 mm from the edge of the wafer 29 in the case of a 200 mm wafer 29. This tends to induce stress on the edge of the wafer 29, causing warpage of the wafer 29 and negatively impacting subsequent photolithography processes.

Another drawback associated with the conventional wafer boat 24 is that the total surface area of the pin contact points 31 on each wafer 29 is typically about 400 mm². Since particles tend to accumulate at the interface contact points 31 between the wafer support pins 30 and the wafer 29 during the deposition process, this provides excessive contact surface area for the accumulation of potential device-contaminating particles on the backside of the wafer 29.

Therefore, a novel wafer boat having specially-designed wafer support pins is needed for supporting wafers at or near the center of gravity of each wafer and minimizing the contact surface area between the wafer support pins and the wafer during a deposition process.

Accordingly, an object of the present invention is to provide a new and improved wafer boat suitable for supporting wafers in such a manner as to prevent or minimize warpage and/or particulate contamination of the wafers during processing.

Another object of the present invention is to provide a new and improved wafer boat fitted with wafer support pins that contact the backside of a wafer at or near the center of gravity of the wafer.

Still another object of the present invention is to provide a new and improved wafer boat fitted with wafer support pins that contact the backside of a wafer at contact points having a minimum contact surface area.

Yet another object of the present invention is to provide a new and improved wafer boat which supports multiple wafers in such a manner as to minimize generation of particles during wafer processing.

### SUMMARY OF THE INVENTION

In accordance with these and other objects and advantages, the present invention is generally directed to a wafer boat which is suitable for eliminating or at least reducing wafer warpage and particle generation during the furnace processing of wafers, for example. The wafer boat typically includes a base plate and multiple vertical support rods extending from the base plate. Multiple, vertically-spaced wafer support pins extend from each support rod, and wafer support pins on the respective support rods support a corresponding one of the wafers during processing. The upper surface of each wafer support pin is disposed at an acute angle with respect to the longitudinal axis of the support rod to minimize the contact surface area of each wafer support pin with the backside of the wafer, reducing the accumulation of particles between the wafer support pin and the wafer. Furthermore, the wafer support pins support each wafer at or near the center of gravity of the wafer, preventing or substantially reducing warpage of the wafer during processing.

### BRIEF DESCRIPTION OF THE DRAWINGS

The invention will now be described, by way of example, with reference to the accompanying drawings, in which:

FIG. 1 is a sectional view of a typical conventional LPCVD process furnace;

FIG. 1A is a side view of a conventional wafer boat used in conjunction with the furnace of FIG. 1, illustrating multiple wafer support pins extending from a pair of the support rods and supporting each of multiple wafers during processing of the wafers;

FIG. 1B is a top view of a wafer, illustrating multiple pin contact points of the wafer support pins on the conventional wafer boat with the wafer;

FIG. 2 is a perspective view, partially in section, of a wafer boat of the present invention, with the wafer support pins of the wafer boat not shown;

FIG. 3 is a sectional view, taken along section lines 3-3 in FIG. 2, of a wafer boat according to the present invention;

FIG. 4 is an enlarged side view, partially in section, of a wafer support pin of the wafer boat according to the present invention;

FIG. 5 is a side view, partially in section, of the wafer boat according to the present invention, illustrating multiple wafer support pins extending from a pair of the support rods and supporting multiple wafers during processing of the wafers; and

FIG. 6 is a top view of a wafer, illustrating multiple pin contact points on the wafer and defined by the respective wafer support pins on the wafer boat of the present invention.

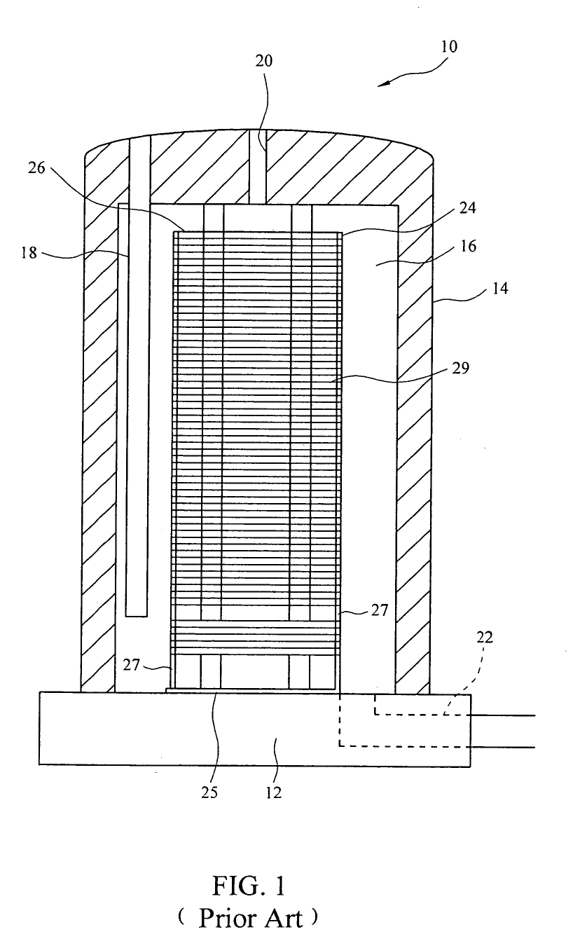

### DESCRIPTION OF THE PREFERRED EMBODIMENTS

The present invention contemplates a wafer boat which is suitable for holding multiple wafers in a vertical processing furnace and eliminating or at least substantially reducing wafer warpage and particle generation during processing of the wafers. In an illustrative embodiment, the wafer boat includes a base plate and multiple vertical support rods extending from the base plate. Multiple wafer support pins extend from each support rod in vertically-spaced relationship to each other. A wafer support pin on each support rod, in conjunction with a wafer support pin on each of the other support rods, supports a corresponding one of the wafers during processing. Each wafer support pin has a generally tapered configuration such that the upper surface of each wafer support pin is disposed at an acute angle with respect to the longitudinal axis of the support rod. When a wafer is supported on the wafer support pins, the contact surface area of each wafer support pin with the backside of the wafer is minimized, thus reducing the accumulation of particles between each wafer support pin and the wafer. Furthermore, the wafer support pins contact the backside of each wafer at or near the center of gravity of the wafer. This prevents or substantially reduces warpage of the wafer caused by thermal and gravity gradients during processing.

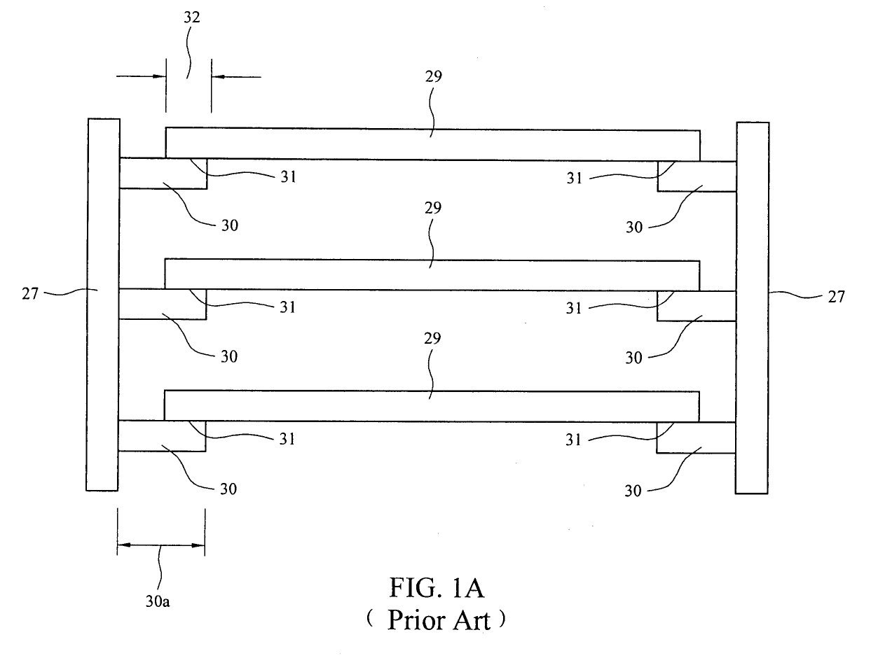

Referring to FIGS. 2-4, an illustrative embodiment of the wafer boat of the present invention is generally indicated by reference numeral 34. The wafer boat 34 having the dimensions which will be hereinafter described is specifically adapted to support 200 mm wafers in a processing furnace or chamber. However, it is understood that the dimensions of the wafer boat 34 can be adapted to support wafers of larger or smaller size, as desired. The wafer boat 34 may be constructed of quartz, silicon carbide (SiC), silicon (Si) or other corrosion-resistant and heat-resistant materials known by those skilled in the art. As shown in FIG. 2, the wafer boat 34 typically includes a generally flat, circular base plate 36. Multiple, elongated support rods 40 extend from the base plate 36, in generally parallel, spaced-apart relationship to each other. A generally flat, circular top plate 38 is typically supported on the upper ends of the support rods 40.

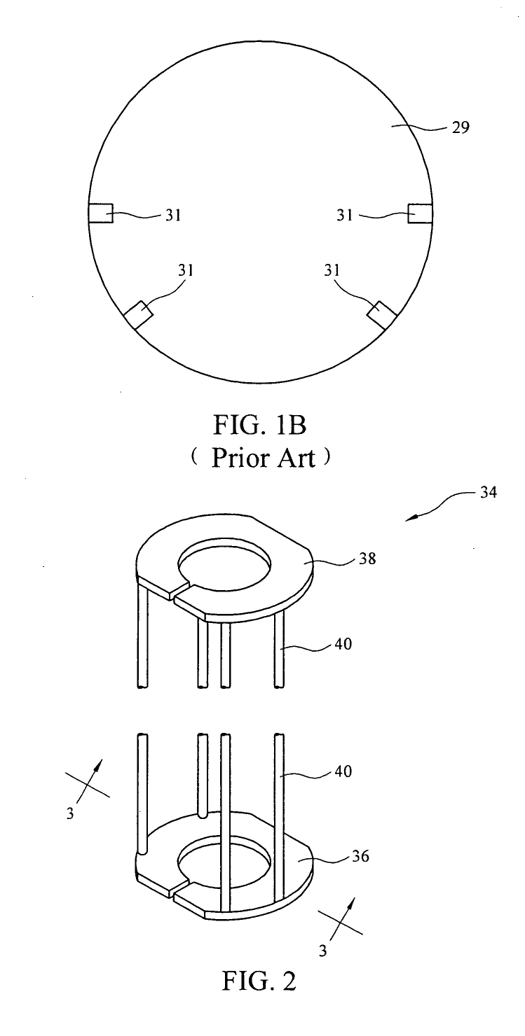

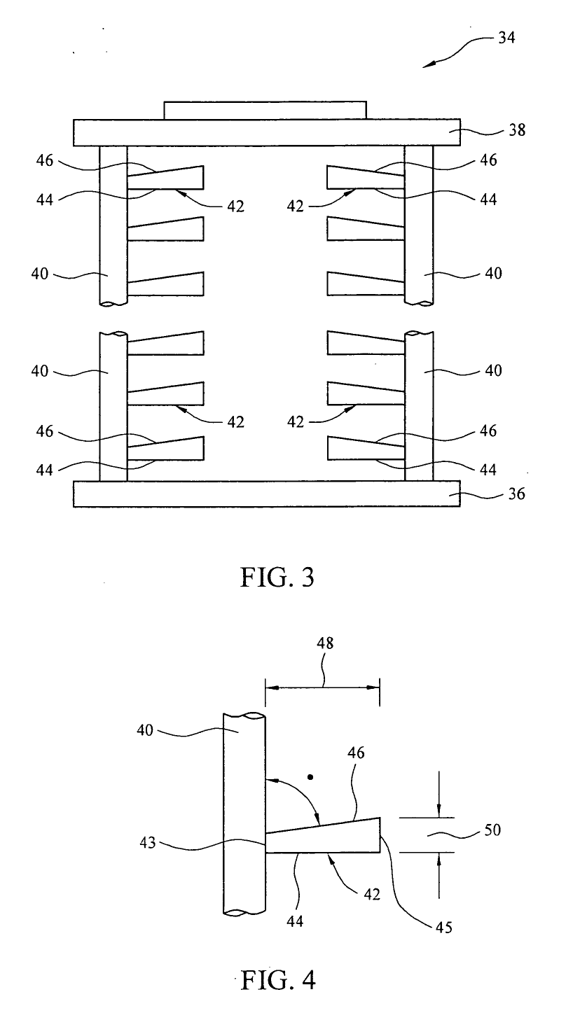

As shown in FIG. 3, multiple wafer support pins 42 extend from each support rod 40 in generally parallel, spaced-apart relationship to each other. Each wafer support pin 42 which extends each support rod 40 at a particular height is disposed in the same generally horizontal plane as the other wafer support pins 42 that extend from the other support rods 40, respectively, at that height. As shown in FIG. 4, each wafer support pin 42 includes a proximal end 43 which is attached to or continuous with the support rod 40 and a distal end 45 which is spaced from the proximal end 43. Each wafer support pin 42 further includes a lower surface 44 which is disposed at generally a 90-degree angle with respect to the longitudinal axis of the support rod 40 from which the wafer support pin 42 extends. An upper surface 46 of the wafer support pin 42 is disposed at an acute angle “a” with respect to the longitudinal axis of the support rod 40. Preferably, the angle “α” is from typically about 70 degrees to typically about 89 degrees. Most preferably, the angle “α” is typically about 88.5 degrees. Thus, each wafer support pin 42 tapers from the relatively wide distal end 45 to the relatively narrow proximal end 43.

In the case of a wafer boat 34 designed to support 200 mm wafers, the pin length 48 of each wafer support pin 42 is preferably about 40 mm. However, the pin length 48 may vary depending on the diameter of wafers to be supported on the wafer boat 34. The pin thickness 50 of each wafer support pin 42 is typically about 3.0 mm.

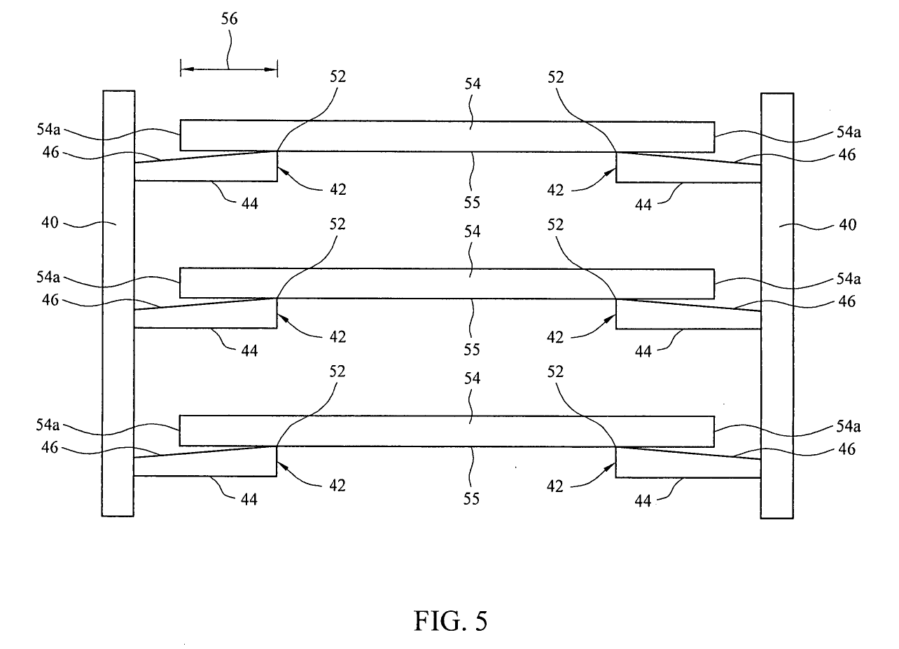

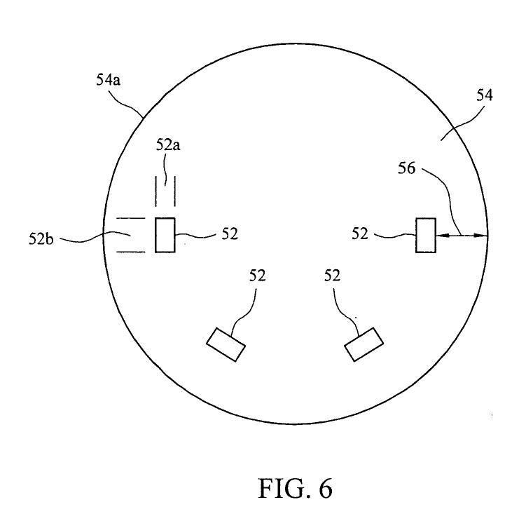

Referring next to FIGS. 5 and 6, in application of the invention, the wafer boat 34 is used to support multiple wafers 54 in a process chamber (not shown) such as a vertical LPCVD furnace as an LPCVD process is carried out in the furnace. As shown in FIG. 5, each wafer 54 is supported by a set of multiple, generally coplanar wafer support pins 42 which extend from the respective support rods 40 at substantially the same height. Accordingly, the backside 55 of the wafer 54 contacts the upper surface 46 of each wafer support pin 42 at a pin contact point 52. In the case of 200 mm wafers 54, each pin contact point 52 is located at an inset spacing 56 of typically about 30 mm from the edge 54a of the wafer 54, as shown in FIGS. 5 and 6. Furthermore, as shown in FIG. 6, each pin contact point 52 has a width 52a of typically about 5 mm and a length 52b of typically about 10 mm. This provides a total contact surface area of typically about 200 mm² collectively between the wafer support pins 42 and the backside 55 of the wafer 54.

During the LPCVD process carried out in the reaction chamber (not shown), reaction gases (not shown) flow in a substantially uniform path over the surfaces of the wafers 54 supported on the vertically-spaced sets of wafer support pins 42 in the wafer boat 34. Simultaneously, the wafers 54 are heated for the deposition process. Consequently, the wafers 54 are substantially uniformly coated with deposition material, which forms films of uniform thickness on the surfaces of the respective wafers 54.

It will be appreciated by those skilled in the art that the pin contact points 52 of the wafer support pins 42 with the wafer 54 are spaced from the wafer edge 54a by the inset spacing 56 of typically about 30 mm. This is at or near the center of gravity of the wafer 54. Consequently, warpage of each wafer 54, induced by thermal and gravity gradients during processing, is prevented or at least substantially reduced. Furthermore, the combined surface area of the pin contact points 52 on the wafer backside 55 is only about 200 mm². This substantially prevents or minimizes the accumulation of potential device-contaminating particles between the wafer backside 55 and each wafer support pin 42 during the thermal or other process.

While the preferred embodiments of the invention have been described above, it will be recognized and understood that various modifications can be made in the invention and the appended claims are intended to cover all such modifications which may fall within the spirit and scope of the invention.

1. A wafer boat for supporting semiconductor wafers to reduce wafer warping and particulate contamination of wafers during thermal processing, comprising:
a base plate;
a plurality of support rods carried by said base plate; and
a plurality of wafer support pins carried by each of said support rods, each of said wafer support pins having an upper surface disposed at an acute angle with respect to a longitudinal axis of each of said support rods;
whereby said wafer support pins comprise wafer contact points at a distal end thereof, wherein said wafer support pins extend inward from a wafer edge to support said wafer on said wafer contact points at about a center of gravity of said wafer.

2. The wafer boat of claim 1 wherein said acute angle is from about 70 degrees to about 89 degrees.

3. The wafer boat of claim 2 wherein said acute angle is about 88.5 degrees.

4. The wafer boat of claim 1 wherein each of said wafer support pins has a pin length of about 40 mm.

5. The wafer boat of claim 1 wherein each of said wafer support pins has a pin thickness of about 3.0 mm.

6. The wafer boat of claim 1 wherein said plurality of support rods and said plurality of wafer support pins are a material selected from the group consisting of quartz, silicon carbide and silicon.

7. The wafer boat of claim 6 wherein said acute angle is from about 70 degrees to about 89 degrees.

8. The wafer boat of claim 7 wherein said acute angle is about 88.5 degrees.

9. A wafer boat for supporting wafers to prevent warping and particulate contamination of semiconductor wafers during thermal processing, comprising:
a base plate;
a plurality of support rods carried by said base plate; and
a plurality of wafer support pins carried by each of said support rods, each of said wafer support pins having a proximal end, a distal end spaced from said proximal end and a tapered configuration from said distal end to said proximal end.
wherein said distal end forms a wafer contact point that extends in form the wafer edge about 15% of the wafer diameter to support said wafer at about a center of gravity to prevent warping of said wafer during processing.

10. The wafer boat of claim 9 wherein said each of said wafer support pins comprises an upper surface disposed at an acute angle with respect to a longitudinal axis of each of said support rods.

11. The wafer boat of claim 10 wherein each of said wafer support pins comprises a lower surface disposed at substantially a 90-degree angle with respect to said longitudinal axis of each of said support rods.

12. The wafer boat of claim 10 wherein said acute angle is from about 70 degrees to about 89 degrees.

13. The wafer boat of claim 12 wherein said acute angle is about 88.5 degrees.

14. The wafer boat of claim 13 wherein each of said wafer support pins has a pin length of about 40 mm.

15. The wafer boat of claim 13 wherein each of said wafer support pins has a pin thickness of about 3.0 mm.

16. The wafer boat of claim 9 wherein said plurality of support rods and said plurality of wafer support pins are a material selected from the group consisting of quartz, silicon carbide and silicon.

17. A method of supporting a semiconductor wafer in a process furnace, to reduce wafer warping and particulate contamination during thermal processing comprising:
providing a wafer boat comprising a base plate, a plurality of support rods carried by said base plate and a plurality of wafer support pins carried by each of said support rods; and
supporting said wafer on said plurality of wafer support pins, with said wafer support pins contacting said wafer about a center of gravity of said wafer, said center of gravity at about 15% of a wafer diameter from the wafer edge said wafer support pins further ad defining a total surface area of contact of about 200 mm² on said wafer.

18. The method of claim 17 wherein each of said wafer support pins comprises an upper surface disposed at an acute angle with respect to a longitudinal axis of each of said support rods.

19. The method of claim 18 wherein said acute angle is from about 70 degrees to about 89 degrees.

20. The wafer boat of claim 19 wherein said acute angle is about 88.5 degrees.
